(19) United States
(12) Patent Application Publication
(10) Pub. No.: US 2020/0026194 A1
(43) Pub. Date: Jan. 23, 2020

(54) METHOD FOR TREATING SUBSTRATE

(71) Applicant: SEMES CO., LTD., Chungcheongnam-do (KR)

(72) Inventors: HAE-WON CHOI, Daejeon (KR); ANTON KORIAKIN, Cheonan-si (KR); JI SOO JEONG, Seoul (KR); KIHOON CHOI, Cheonan-si (KR); JAESEONG LEE, Hwaseong-si (KR); CHAN YOUNG HEO, Hwaseong-si (KR); DO HEON KIM, Cheonan-si (KR)

(21) Appl. No.: 16/510,641

(22) Filed: Jul. 12, 2019

(30) Foreign Application Priority Data
Jul. 20, 2018 (KR) 10-2018-0084781

(51) Int. Cl. G03F 7/40; G03F 7/16; G03F 7/32; G03F 7/42

(52) U.S. Cl. CPC G03F 7/40; G03F 7/42; G03F 7/325; G03F 7/16

(57) ABSTRACT

A substrate treating method includes performing a developing process on a substrate subjected to an exposing process and a post-bake process by applying a developing fluid to the substrate, applying a rinsing fluid to the substrate subjected to the developing process, and moving, to a high-pressure chamber, the substrate having the rinsing fluid applied thereto and treating the substrate by using a supercritical fluid.

### CROSS-REFERENCE TO RELATED APPLICATIONS

A claim for priority under 35 U.S.C. § 119 is made to Korean Patent Application No. 10-2018-0084781 filed on Jul. 20, 2018, in the Korean Intellectual Property Office, the entire contents of which are hereby incorporated by reference.

### BACKGROUND

Embodiments of the inventive concept described herein relate to a method for treating a substrate.

Various processes, such as photolithography, etching, ashing, ion implantation, thin-film deposition, cleaning, and the like, are performed on a substrate to manufacture a semiconductor device or a liquid crystal display. Among these processes, the photolithography process for forming a desired circuit pattern on the substrate includes a coating process, an exposing process, and a developing process that are performed in a serial order. In the coating process, a light-sensitive liquid such as photoresist is applied to the substrate. In the exposing process, the photoresist film formed on the substrate is exposed to a pattern of intense light. In the developing process, the region of the photoresist film exposed to the light is selectively developed. Thereafter, the developing fluid used in the developing process is removed from the substrate, and the substrate is dried.

### SUMMARY

Embodiments of the inventive concept provide a substrate treating method for suppressing generation of particles or contaminants and improving substrate treating efficiency.

According to an exemplary embodiment, a substrate treating method includes performing a developing process on a substrate subjected to an exposing process and a post-bake process by applying a developing fluid to the substrate, applying a rinsing fluid to the substrate subjected to the developing process, and moving, to a high-pressure chamber, the substrate having the rinsing fluid applied thereto and treating the substrate by using a supercritical fluid.

According to an embodiment, the rinsing fluid may be hydrofluoroether (HFE).

According to an embodiment, the rinsing fluid may be n-butyl acetate.

According to an embodiment, the rinsing fluid may be 2-heptanone.

According to an embodiment, the rinsing fluid may be isopropyl alcohol (IPA).

According to an embodiment, the developing fluid may be used to develop negative photoresist.

According to an embodiment, the developing fluid may be n-butyl acetate or isopropyl alcohol (IPA).

According to an embodiment, the supercritical fluid may be carbon dioxide.

According to an exemplary embodiment, a substrate treating method includes transferring, to a first chamber, a substrate subjected to an exposing process and a post-bake process, performing a developing process on the substrate by applying a developing fluid to the substrate in the first chamber, transferring, to a second chamber, the substrate subjected to the developing process, applying a rinsing fluid to the substrate in the second chamber, moving, to a high-pressure chamber, the substrate having the rinsing fluid applied thereto, and treating the substrate by using a supercritical fluid in the high-pressure chamber.

According to an embodiment, the rinsing fluid may be selected from the group consisting of hydrofluoroether (HFE), n-butyl acetate, 2-heptanone, and isopropyl alcohol (IPA).

According to an embodiment, the developing fluid may be n-butyl acetate or isopropyl alcohol (IPA).

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view illustrating a substrate treating apparatus according to an embodiment of the inventive concept;

FIG. 2 is a sectional view illustrating a first liquid treating chamber of FIG. 1;

FIG. 3 is a sectional view illustrating an embodiment of a second liquid treating chamber of FIG. 1;

FIG. 4 is a sectional view illustrating another embodiment of a liquid treating chamber 3000 of FIG. 1;

FIG. 5 is a sectional view illustrating an embodiment of a high-pressure chamber of FIG. 1;

FIG. 6 is a view illustrating a process of treating a substrate according to an embodiment; and

FIG. 7 is a view illustrating a process of treating a substrate according to another embodiment.

### DETAILED DESCRIPTION

Hereinafter, embodiments of the inventive concept will be described in more detail with reference to the accompanying drawings. The inventive concept may, however, be embodied in different forms and should not be constructed as limited to the embodiments set forth herein. Rather, these embodiments are provided so that the inventive concept will be thorough and complete, and will fully convey the scope of the inventive concept to those skilled in the art. In the drawings, the dimensions of components are exaggerated for clarity of illustration.

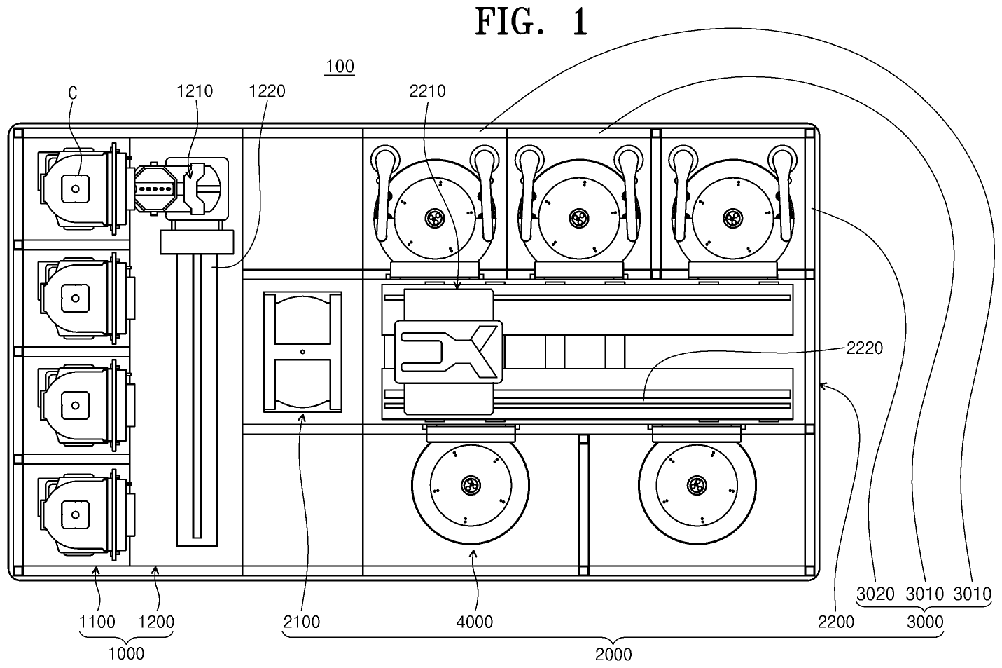

FIG. 1 is a plan view illustrating a substrate treating apparatus according to an embodiment of the inventive concept. The substrate treating apparatus 100 according to the inventive concept will be described below with reference to FIG. 1. Here, substrates S have a comprehensive concept that includes all substrates used to manufacture semiconductor devices, flat panel displays (FPDs), and other objects having a circuit pattern formed on a thin film thereof. Examples of the substrates S include a silicon wafer, a glass substrate, an organic substrate, and the like. The substrates S loaded into the substrate treating apparatus 100 from the outside are substrates already subjected to a photoresist coating process, an exposing process, and a post-bake process.

The substrate treating apparatus 100 includes an index module 1000 and a process module 2000.

The index module 1000 receives the substrates S from the outside and transfers the substrates S to the process module 2000. The process module 2000 performs cleaning and drying processes on the substrates S.

The index module 1000, which is an equipment front end module (EFEM), includes load ports 1100 and a transfer frame 1200.

Carriers C having the substrates S received therein are placed on the load ports 1100. Front opening unified pods (FOUPs) may be used as the carriers C.

The carriers C may be carried from the outside to the load ports 1100, or vice versa, by an overhead transfer (OHT).

The transfer frame 1200 transfers the substrates S between the carriers C placed on the load ports 1100 and the process module 2000. The transfer frame 1200 includes an index robot 1210 and an index rail 1220. The index robot 1210 may move on the index rail 1220 and may transfer the substrates S.

The process module 2000 includes a buffer chamber 2100, a transfer chamber 2200, liquid treating chambers 3000, and high-pressure chambers 4000.

The buffer chamber 2100 provides a space in which the substrates S transferred between the index module 1000 and the process module 2000 temporarily stay. The buffer chamber 2100 may have buffer slots therein. The substrates S are placed on the buffer slots. For example, the index robot 1210 may extract the substrates S from the carriers C and may place the substrates S on the buffer slots. A transfer robot 2210 of the transfer chamber 2200 may extract the substrates S placed on the buffer slots and may transfer the substrates S to the liquid treating chambers 3000 or the high-pressure chambers 4000. The buffer chamber 2100 may include the plurality of buffer slots, and the plurality of substrates S may be placed on the plurality of buffer slots.

The transfer chamber 2200 transfers the substrates S between the buffer chamber 2100, the liquid treating chambers 3000, and the high-pressure chambers 4000 that are disposed around the transfer chamber 2200. The transfer chamber 2200 includes the transfer robot 2210 and a transfer rail 2220. The transfer robot 2210 may move on the transfer rail 2220 and may transfer the substrates S.

The liquid treating chambers 3000 and the high-pressure chambers 4000 treat the substrates S. The liquid treating chambers 3000 and the high-pressure chambers 4000 are disposed on sides of the transfer chamber 2200. For example, the liquid treating chambers 3000 and the high-pressure chambers 4000 may be disposed on opposite sides of the transfer chamber 2200 to face each other.

The liquid treating chambers 3000 include first liquid treating chambers 3010 and a second liquid treating chamber 3020. The first liquid treating chambers 3010 apply a developing fluid to the substrates S. The second liquid treating chamber 3020 applies a rinsing fluid to the substrates S. The arrangement of the first liquid treating chambers 3010 and the second liquid treating chamber 3020 is not limited to the above-described embodiment and may be modified in consideration of the footprint and process efficiency of the substrate treating apparatus 100.

The process module 2000 may include the plurality of liquid treating chambers 3000 and the plurality of high-pressure chambers 4000. The arrangement of the liquid treating chambers 3000 and the high-pressure chambers 4000 is not limited to the above-described embodiment and may be modified in consideration of the footprint and process efficiency of the substrate treating apparatus 100. For example, on the sides of the transfer chamber 2200, the plurality of process chambers 3000 and 4000 may be arranged in a row, may be vertically stacked one above another, or may be arranged by a combination thereof.

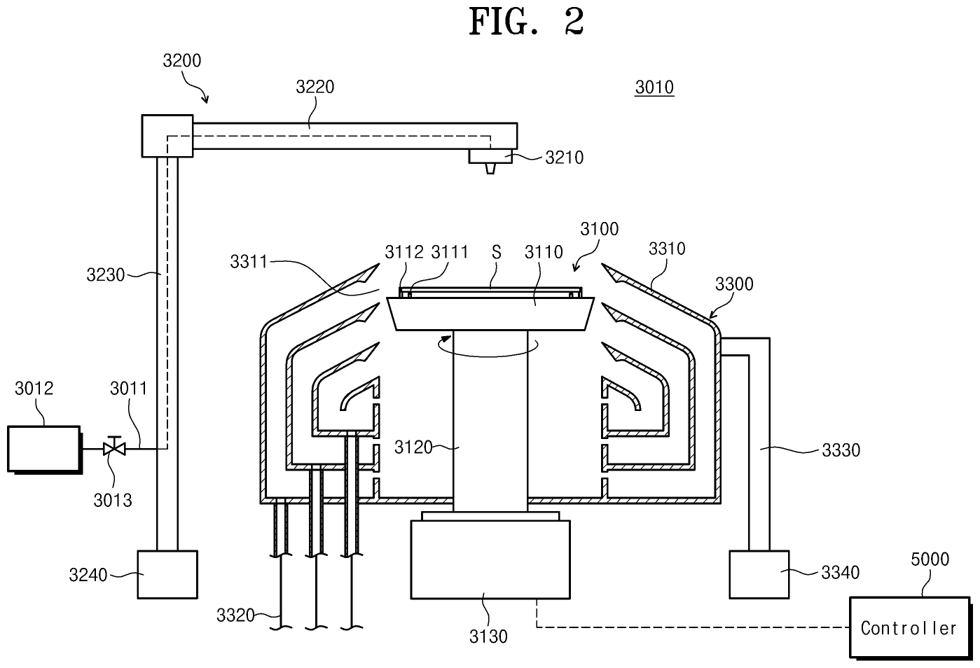

The substrate treating apparatus 100 may be controlled by a controller 5000 (refer to FIG. 2).

FIG. 2 is a sectional view illustrating the first liquid treating chamber of FIG. 1. The first liquid treating chamber 3010 includes a support member 3100, a nozzle member 3200, and a recovery member 3300.

The first liquid treating chamber 3010 performs a developing process on a substrate S by applying a developing fluid to the substrate S already subjected to an exposing process and a post-bake process.

The support member 3100 supports the substrate S. The support member 3100 may rotate the substrate S supported thereon. The support member 3100 includes a support plate 3110, support pins 3111, chuck pins 3112, a rotary shaft 3120, and a rotary actuator 3130.

The support plate 3110 has an upper surface in a shape that is the same as, or similar to, the substrate S. The support pins 3111 and the chuck pins 3112 are provided on the upper surface of the support plate 3110. The support pins 3111 support the backside of the substrate S. The chuck pins 3112 may fix the supported substrate S.

The rotary shaft 3120 is connected to a lower portion of the support plate 3110. The rotary shaft 3120 receives a rotational force from the rotary actuator 3130 and rotates the support plate 3110. Accordingly, the substrate S placed on the support plate 3110 may be rotated. The chuck pins 3112 prevent the substrate S from escaping from the correct position.

The nozzle member 3200 dispenses a process fluid onto the substrate S. The nozzle member 3200 includes a nozzle 3210, a nozzle bar 3220, a nozzle shaft 3230, and a nozzle shaft actuator 3240.

The nozzle 3210 dispenses the developing fluid onto the substrate S placed on the support plate 3110. The nozzle 3210 is formed on the bottom of one end of the nozzle bar 3220. The nozzle bar 3220 is combined with the nozzle shaft 3230. The nozzle 3230 is implemented to move up and down or rotate. The nozzle shaft actuator 3240 may raise/lower or rotate the nozzle shaft 3230 to adjust the position of the nozzle 3210. The nozzle 3210 is connected with a developing fluid supply line 3011. The developing fluid supply line 3011 is connected to a developing fluid source 3012. A valve 3013 is installed in the developing fluid supply line 3011. The developing fluid supplied is n-butyl acetate or isopropyl alcohol (IPA).

The recovery member 3300 recovers the process fluid dispensed onto the substrate S. When the process fluid is dispensed onto the substrate S by the nozzle member 3200, the support member 3100 may rotate the substrate S to allow the process fluid to spread over the entire area of the substrate S. The process fluid is scattered from the substrate S when the substrate S is rotated. The process liquid scattered may be recovered by the recovery member 3300.

The recovery member 3300 includes a recovery bowl 3310, a recovery line 3320, a lifting bar 3330, and a lifting actuator 3340.

The recovery bowl 3310 has an annular ring shape that surrounds the support plate 3110. A plurality of recovery bowls 3310 may be provided. The plurality of recovery bowls 3310 may be implemented in ring shapes that are spaced farther away from the support plate 3110 in a serial order when viewed from above. The heights of the recovery bowls 3310 may be sequentially increased with an increase in the distance from the support plate 3110. The recovery bowls 3310 may have a recovery opening 3311 therebetween, through which the substrate cleaning composition scattered from the substrate S is introduced. The recovery line 3320 may be formed at the bottom of each of the recovery bowls 3310.

The lifting bar 3330 is connected to the recovery bowl 3310. The lifting bar 3330 receives power from the lifting actuator 3340 and moves the recovery bowl 3310 up and down. In the case where the plurality of recovery bowls 3310 are provided, the lifting bar 3330 may be connected to the outermost recovery bowl 3310. The lifting actuator 3340 may raise/lower the recovery bowls 3310 through the lifting bar 3330 to adjust which of the recovery openings 3311 is used to introduce the scattered process fluid.

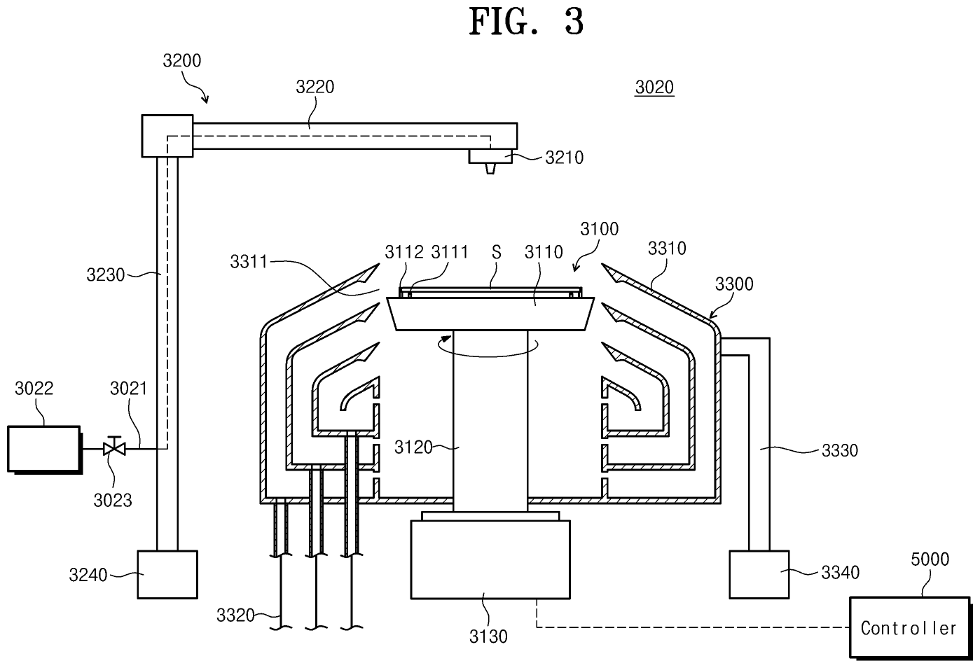

FIG. 3 is a sectional view illustrating an embodiment of the second liquid treating chamber of FIG. 1.

Components of the second liquid treating chamber 3020 that are identical to the components of the first liquid treating chamber 3010 are denoted by the identical reference numerals, and descriptions thereabout are replaced with the descriptions of FIG. 2.

The second liquid treating chamber 3020 applies a rinsing fluid to the substrate S treated with the developing fluid. The nozzle 3210 dispenses the rinsing fluid onto the substrate S placed on the support plate 3110. The nozzle 3210 of the second liquid treating chamber 3020 is connected with a rinsing fluid supply line 3021. The rinsing fluid supply line 3021 is connected to a rinsing fluid source 3022. A valve 3023 is installed in the rinsing fluid supply line 3021. The rinsing fluid supplied is selected from the group consisting of hydrofluoroether (HFE), n-butyl acetate, 2-heptanone, and isopropyl alcohol (IPA).

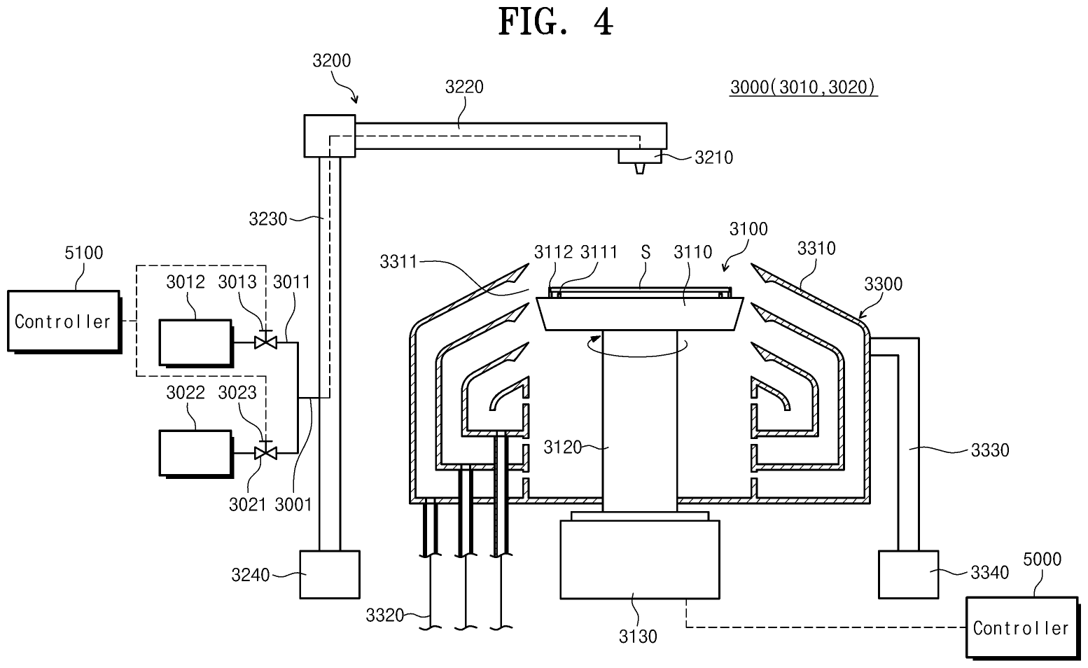

FIG. 4 is a sectional view illustrating another embodiment of the liquid treating chamber 3000 of FIG. 1.

Referring to FIG. 4, the functions of the first liquid treating chamber 3010 of FIG. 2 and the second liquid treating chamber 3020 of FIG. 3 may be integrated with each other and may be provided by a single liquid treating chamber.

Components of the integrated liquid treating chamber 3000 that are identical to the components of the first liquid treating chamber 3010 are denoted by the identical reference numerals, and descriptions thereabout are replaced with the descriptions of FIG. 2.

The integrated liquid treating chamber 3000 applies a developing fluid to a substrate S already subjected to an exposing process and a post-bake process to perform a developing process on the substrate S, and then applies a rinsing fluid to the substrate S.

The nozzle 3210 of the integrated liquid treating chamber 3000 is connected with a liquid supply line 3001. The liquid supply line 3001 is connected with the developing fluid supply line 3011 and the rinsing fluid supply line 3021. The developing fluid supply line 3011 and the rinsing fluid supply line 3021 are connected, at one point, with the liquid supply line 3001. The developing fluid supply line 3011 is connected to the developing fluid source 3012. The rinsing fluid supply line 3021 is connected to the rinsing fluid source 3022. The valve 3013 is installed in the developing fluid supply line 3011, and the valve 3023 is installed in the rinsing fluid supply line 3021.

The developing fluid supplied is n-butyl acetate or isopropyl alcohol (IPA), and the rinsing fluid supplied is selected from the group consisting of hydrofluoroether (HFE), n-butyl acetate, 2-heptanone, and isopropyl alcohol (IPA).

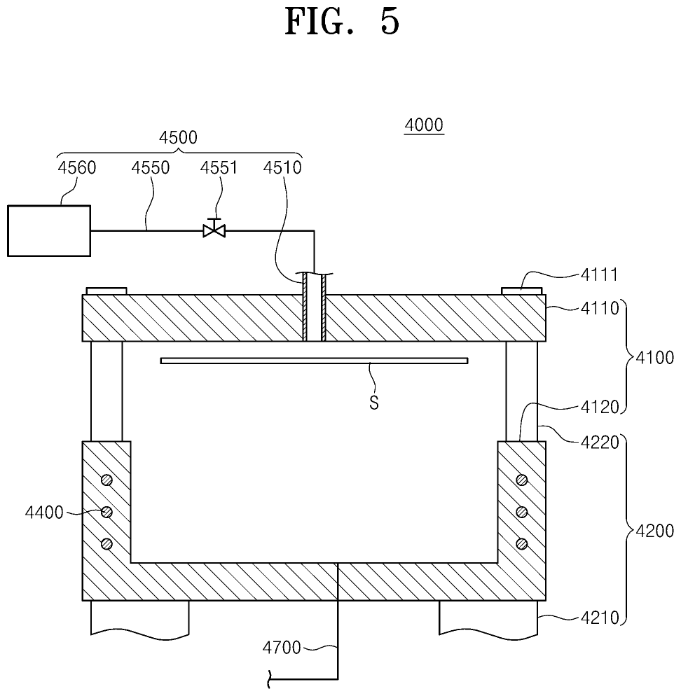

FIG. 5 is a sectional view illustrating an embodiment of the high-pressure chambers of FIG. 1.

Referring to FIG. 5, the high-pressure chamber 4000 includes a chamber 4100, a lifting unit 4200, a support unit (not illustrated), a heating member 4400, a fluid supply unit 4500, a blocking member (not illustrated), and an exhaust member 4700. The high-pressure chamber 4000 performs a process of treating a substrate S by using a supercritical fluid.

The chamber 4100 has a processing space inside, in which a supercritical cleaning or drying process is performed. The chamber 4100 is made of a material that is capable of resisting high pressure above the critical pressure.

The chamber 4100 includes an upper body 4110 and a lower body 4120. The upper body 4110 is combined with the lower body 4120 to form the processing space inside. The upper body 4110 is located over the lower body 4120. The upper body 4110 may have a rectangular plate shape, and the lower body 4120 may have a rectangular cup shape that is open at the top.

In the position in which the central axis of the upper body 4110 is aligned with the central axis of the lower body 4120, the upper body 4110 may be provided such that a lower end of the upper body 4110 faces an upper end of the lower body 4120. According to an embodiment, the upper body 4110 and the lower body 4120 may be made of metal.

The upper body 4110 is fixed to an external structure. The lower body 4120 is movable up and down relative to the upper body 4110. The processing space of the high-pressure chamber 4000 is open when the lower body 4120 moves downward and is spaced apart from the upper body 4110. The substrate S may be placed in, or extracted from, the processing space of the high-pressure chamber 4000 that is open. Here, the substrate S placed in the high-pressure chamber 4000 has a rinsing fluid remaining thereon.

The processing space of the high-pressure chamber 4000 is closed when the lower body 4120 moves upward and is brought into close contact with the upper body 4110. In the closed processing space, the substrate S may be treated by the supercritical fluid. In contrast to the embodiment described above, the chamber 4100 may have a structure in which the lower body 4120 is fixed and the upper body 4110 is raised or lowered.

The lifting unit 4200 raises or lowers the lower body 4120. The lifting unit 4200 includes a lifting cylinder 4210 and a lifting rod 4220. The lifting cylinder 4210 is combined with the lower body 4120 and generates a driving force in the vertical direction. The lifting cylinder 4210 generates a driving force that is sufficient to withstand the high pressure above the critical pressure in the high-pressure chamber 4000 and to bring the lower body 4120 into close contact with the upper body 4110 to close the high-pressure chamber 4000, while the substrate S is treated by using the supercritical fluid. The lifting rod 4220 extends in the vertical direction and has one end inserted into the lifting cylinder 4210 and an opposite end combined with the upper body 4110. When the lifting cylinder 4210 generates a driving force, the lifting cylinder 4210 and the lifting rod 4220 may be relatively raised, and therefore the lower body 4120 combined with the lifting cylinder 4210 may be raised. While the lower body 4120 is raised by the lifting cylinder 4210, the lifting rod 4220 may prevent a horizontal movement of the upper body 4110 and the lower body 4120 and may guide the lifting direction to prevent the upper body 4110 and the lower body 4120 from escaping from the correct positions.

Meanwhile, although not illustrated in the drawing, a substrate support unit (not illustrated) that supports the substrate S may be provided in the processing space. The substrate support unit (not illustrated) supports the substrate S such that a surface of the substrate S that is to be treated faces upward.

The substrate support unit (not illustrated) is located in the processing space of the chamber 4100 and supports the substrate S. The substrate support unit (not illustrated) may be combined with the upper body 4110. Because the substrate support unit (not illustrated) is combined with the upper body 4110, the substrate support unit (not illustrated) may stably support the substrate S while the lower body 4120 is raised or lowered.

The substrate support unit (not illustrated) may support the substrate S in contact with the edge region of the substrate S, and therefore substrate treatment using the supercritical fluid may be performed on the entire upper surface of the substrate S and most of the lower surface of the substrate S. Here, the upper surface of the substrate S may be a patterned surface, and the lower surface of the substrate S may be an unpatterned surface.

The heating member 4400 heats the interior of the high-pressure chamber 4000. The heating member 4400 heats the supercritical fluid supplied into the high-pressure chamber 4000 to the critical temperature or more to maintain the supercritical fluid in a supercritical fluid phase. When the supercritical fluid is liquefied, the heating member 4400 may heat the supercritical fluid to allow the supercritical fluid to return to the supercritical fluid phase. The heating member 4400 is buried in the wall of at least one of the upper body 4110 and the lower body 4120. The heating member 4400 receives electric power from the outside and generates heat. For example, the heating member 4400 may be implemented with a heater.

The fluid supply unit 4500 supplies fluid into the high-pressure chamber 4000. The fluid supplied may be a supercritical fluid. For example, the supercritical fluid may be carbon dioxide.

The fluid supply unit 4500 includes a supply port 4510, a fluid supply line 4550, and a valve 4551.

The supply port 4510 functions as a passage through which the supercritical fluid is supplied into the processing space. For example, the supply port 4510 may be formed in the upper body 4110. In addition, the supply port 4510 may be located in the center of the upper body 4110.

Alternatively, the supply port 4510 may include an upper supply port 4510 that is formed in the upper body 4110 and a lower supply port (not illustrated) that is formed in the lower body 4120. The fluid supply line 4450, which will be described below, may be split into two branch lines that connect to the upper supply port 4510 and the lower supply port (not illustrated). The branch line connected with the upper supply port 4510 and the branch line connected with the lower supply port (not illustrated) may have the valves 4551 installed therein, respectively.

The supercritical fluid injected through the supply port 4510 reaches the central region of the substrate S and spreads toward the edge region of the substrate S to uniformly cover the entire area of the substrate S.

The fluid supply line 4550 is connected with the supply port 4510. The supercritical fluid is supplied to the supply port 4510 from a separate external supercritical fluid reservoir 4560 through the fluid supply line 4550.

The valve 4551 is installed in the fluid supply line 4550. A plurality of valves 4551 may be provided in the fluid supply line 4550. Each of the valves 4551 regulates the amount of supercritical fluid supplied to the supply port 4510. The controller 5000 may control the valves 4551 to adjust the amount of supercritical fluid supplied into the chamber 4100.

The exhaust member 4700 releases the supercritical fluid from the high-pressure chamber 4000. The supercritical fluid released through the exhaust member 4700 may be discharged into the air or may be supplied to a supercritical fluid regeneration system (not illustrated). The exhaust member 4700 may be combined with the lower body 4120. The exhaust member 4700 includes an exhaust port (not illustrated) through which the supercritical fluid in the processing space is released. For example, the exhaust port (not illustrated) may be formed in the lower body 4120. In addition, the exhaust port (not illustrated) may be located in the center of the lower body 4120.

In the case where the lower supply port (not illustrated) is formed in the lower body 4120, the lower supply port (not illustrated) may be located so as not to interfere with the exhaust member 4700. For example, in the case where the exhaust member 4700 is provided at the center of the lower body 4120, the lower supply port (not illustrated) may be spaced apart from the center of the lower body 4120 by a predetermined distance.

In the later stage of the substrate treating process using the supercritical fluid, the supercritical fluid is released from the high-pressure chamber 4000 so that the pressure in the high-pressure chamber 4000 is reduced to the critical pressure or less and the supercritical fluid may be liquefied. The liquefied supercritical fluid may be released through the exhaust member 4700, which is formed in the lower body 4120, by the force of gravity.

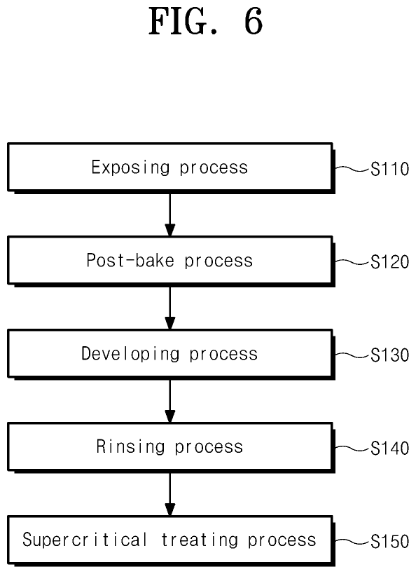

FIG. 6 is a view illustrating a process of treating a substrate according to an embodiment.

Referring to FIG. 6, the substrate treating apparatus 100 treats, according to a set process, a substrate S already subjected to a photoresist coating process, an exposing process, and a post-bake process (S110 and S120). The photoresist with which the substrate S is coated may be negative photoresist.

A developing fluid is dispensed onto the substrate S (S130). The developing fluid may be used to perform a developing process on the substrate S. The developing fluid may be n-butyl acetate or isopropyl alcohol (IPA).

A rinsing fluid is dispensed onto the substrate S subjected to the developing process (S140). The rinsing fluid removes the developed photoresist by-products and the remaining developing fluid. The rinsing fluid is an organic solvent that can be mixed with the developing fluid, can be dissolved and extracted in a supercritical fluid, which will be described below, and does not affect the photoresist pattern formed in the developing process. The rinsing fluid is selected from the group consisting of hydrofluoroether (HFE), n-butyl acetate, 2-heptanone, and isopropyl alcohol (IPA). The rinsing fluid is removed from the substrate S by dissolving and extracting the rinsing fluid by dispensing the supercritical fluid onto the substrate S that has the rinsing fluid remaining thereon (S150).

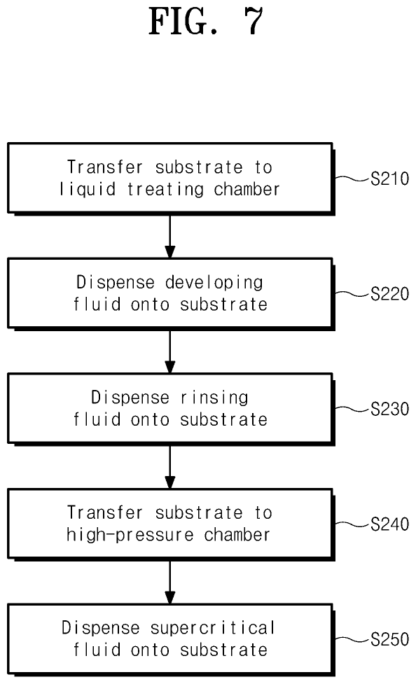

FIG. 7 is a view illustrating a process of treating a substrate according to another embodiment.

In a state of being post-baked after being coated with negative photoresist and exposed to light, a substrate S is transferred to the liquid treating chamber 3000 of FIG. 4 (S210).

A developing fluid is dispensed onto the substrate S in the liquid treating chamber 3000 (S220). The developing fluid supplied may be n-butyl acetate or isopropyl alcohol (IPA).

After the developing process is completely performed, a ring fluid is dispensed onto the substrate S (S230). The rinsing fluid is selected from the group consisting of hydrofluoroether (HFE), n-butyl acetate, 2-heptanone, and isopropyl alcohol (IPA).

The substrate S having the rinsing fluid remaining thereon is transferred to the high-pressure chamber 4000 (S240). The rinsing fluid is removed from the substrate S by dissolving and extracting the rinsing fluid by dispensing a supercritical fluid onto the substrate S transferred into the high-pressure chamber 4000 (S250).

According to the embodiments, the inventive concept may suppress generation of particles or contaminants and may improve substrate treating efficiency.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A substrate treating method comprising:
performing a developing process on a substrate subjected to an exposing process and a post-bake process, by applying a developing fluid to the substrate;
applying a rinsing fluid to the substrate subjected to the developing process; and
moving, to a high-pressure chamber, the substrate having the rinsing fluid applied thereto and treating the substrate by a supercritical fluid.

2. The substrate treating method of claim 1, wherein the rinsing fluid is hydrofluoroether (HFE).

3. The substrate treating method of claim 1, wherein the rinsing fluid is n-butyl acetate.

4. The substrate treating method of claim 1, wherein the rinsing fluid is 2-heptanone.

5. The substrate treating method of claim 1, wherein the rinsing fluid is isopropyl alcohol (IPA).

6. The substrate treating method of claim 1, wherein the developing fluid is used to develop negative photoresist.

7. The substrate treating method of claim 1, wherein the developing fluid is n-butyl acetate or isopropyl alcohol (IPA).

8. The substrate treating method of claim 1, wherein the supercritical fluid is carbon dioxide.

9. A substrate treating method comprising:
transferring, to a first chamber, a substrate subjected to an exposing process and a post-bake process;
performing a developing process on the substrate by applying a developing fluid to the substrate in the first chamber;
transferring, to a second chamber, the substrate subjected to the developing process;
applying a rinsing fluid to the substrate in the second chamber;
moving, to a high-pressure chamber, the substrate having the rinsing fluid applied thereto; and
treating the substrate by a supercritical fluid in the high-pressure chamber.

10. The substrate treating method of claim 9, wherein the rinsing fluid is selected from the group consisting of hydrofluoroether (HFE), n-butyl acetate, 2-heptanone, and isopropyl alcohol (IPA).

11. The substrate treating method of claim 9, wherein the developing fluid is n-butyl acetate or isopropyl alcohol (IPA).
